(19) United States
(12) Patent Application Publication
(10) Pub. No.: US 2009/0170027 A1
(43) Pub. Date: Jul. 2, 2009

(54) OPTICAL RECORDING MEDIUM

(76) Inventors: Hubert C.F. Martens, Eindhoven (NL); Dariusz P. Sobczyk, Eindhoven (NL); Roger M.J. Paffen, Eindhoven (NL)

Correspondence Address: Muncy, Geissler, Olds & Lowe, PLLC, P.O. BOX 1364, FAIRFAX, VA, 22038-1364, US

(21) Appl. No.: 12/304,716

(22) PCT Filed: Jun. 11, 2007
(86) PCT No.: PCT/IB07/52184

§ 371 Date: Dec. 12, 2008

(30) Foreign Application Priority Data
Jun. 12, 2006 (EP) 06115272.4

(51) Int. Cl. G03F 7/004

(52) U.S. Cl. 430/270.11

(57) ABSTRACT

The present invention provides an optical recording medium (10), comprising at least one recording layer (16) being adapted to form marks upon radiation of a laser beam having a particular recording wavelength, wherein a material constituting the recording layer (16) has an absorption maximum at a wavelength that is 100 nm to 250 nm higher than the recording wavelength. Moreover, the invention describes the use of a material for forming such an optical recording medium (10).

### FIELD OF THE INVENTION

The invention relates to an optical recording medium, comprising at least one recording layer being adapted to form marks upon radiation of a laser beam having a particular recording wavelength.

### BACKGROUND OF THE INVENTION

Generally, it is differentiated between recording media based on sputtered inorganic layers and dye-coated recording media. The former provide a very good performance, but are usually more expensive than the latter.

The general “design-rule” for dye used in the past is that the maximum optical absorption coefficient k of a solid dye film should occur at a wavelength approximately 30-100 nm below the recording wavelength. Thus, the maximum absorption appears at 550-620 nm for DVD+R, and at 680-750 nm for CD-R. An optical recording medium designed according to this design rule ensures a high refractive index n of about 2.0-2.5 at the recording wavelength which provides a high modulation and hence a good signal quality. The resulting low absorption coefficient k ensures a high reflectivity.

FIGS. 1 and 2 illustrate a diagram of a dye-coated CD-R and a dye-coated DVD+R according to the state of the art. In FIGS. 1 and 2 the abscissas show the wavelength λ in nm, whereas the ordinates show the refractive index n and the absorption coefficient k, respectively. In the example of FIG. 1, the upper curve indicates the refractive index n and the lower curve indicates the absorption coefficient k of the recording layer for a dye-coated CD-R versus the wavelength, respectively. The example of FIG. 2 illustrates the refractive index n in the upper curve and the absorption coefficient k in the lower curve of the recording layer for a dye-coated DVD+R versus the wavelength, respectively. The dyes used in the examples of FIGS. 1 and 2 are designed according to the above design-rule.

If the cost related advantage of a dye-coated recording medium shall be achieved in combination with a blu-ray disc (BD) which is a disc adapted to be recorded via a recording device which emits a laser beam having a blue wavelength of approximately 405 nm, the above design-rule would imply that dyes with a maximum absorption in the range of approximately 300-370 nm should be designed for BD-Rs. Even if it is difficult to produce such organic materials, because such small wavelength absorption is only possible with short conjugated systems, which as a consequence have not so strong absorption (smaller dipole-elements), such dyes exist in practice.

Unfortunately, in these dyes it is problematic to combine the optical behaviour regarding the maximum absorption with other requirements such as good stability, solubility in suitable solvents, sharp decomposition range, etc. Thus, up to now, no blu-ray disc exists having a recording layer made from dye that combines all good properties for practical use. It is therefore an object of the present invention to provide an alternative optical recording medium providing good performance at low cost.

### SUMMARY OF THE INVENTION

This object is solved by an optical recording medium according to claim 1 and the usage of a material according to claim 6. Further advantageous developments are outlined in the dependent claims.

In accordance with the invention there is provided an optical recording medium in which a material constituting the recording layer has an absorption maximum at a wavelength that is 100 nm to 250 nm higher than the recording wavelength. With such an optical recording medium good performance can be achieved. If the absorption maximum is at a wavelength smaller than the above mentioned limit of 100 nm, the absorption at the recording wavelength becomes too high. On the other hand, if the absorption maximum is at a wavelength above the mentioned limit of 250 nm, the change in refractive index after recording is too small to create a discernable signal during an optical readout. By abandoning the conventionally used “design-rule” and by determining the allowable range for the absorption maximum the use of materials different from the expensive or low performing “design-rule” materials for producing the recording layer of the recording medium is made possible.

According to the present invention it is also preferred that the material constituting the recording layer is an organic dye compound. This provides the advantage that the recording medium can be produced at lower cost compared to recording media having a recording layer of an inorganic material. Moreover, since organic dye compounds have been used for producing CD-Rs and DVD-Rs, existing infrastructure can be re-used at least partially.

Further, it can be envisaged that the recording wavelength lies in the range of 350-450 nm. At this recording wavelength the present invention can be used most beneficial, since for this recording wavelength there were only recording media available having either a lower performance or a higher price.

A further development of the recording medium of the present invention is that the organic dye compound is one also suitable for forming a recording layer on a DVD-R or a DVD+R. This way developing cost can be saved to a large extent for finding new dyes and already present infrastructure can be re-used partially. Moreover, all requirements like stability, sharp decomposition, etc. are already considered and designed in these dyes.

For the same reason it can be beneficial that the organic dye compound is one also suitable for forming a recording layer on a CD-R.

The present invention also provides the use of a material for forming a recording layer of an optical recording medium, which provides the above mentioned advantages in a similar manner.

These and other aspects of the invention will be apparent from and elucidated with reference to the embodiment described herein after.

### BRIEF DESCRIPTION OF THE DRAWINGS

FIG. 1 illustrates a n-/k-diagram of a dye-coated CD-R according to the state of the art.

FIG. 2 illustrates a n-/k-diagram of a dye-coated DVD+R according to the state of the art.

FIG. 3 illustrates a schematic cross sectional diagram of a recording medium according to the present invention.

FIG. 4A illustrates a calculated reflection of the recording medium according to the present invention.

FIG. 4B illustrates a calculated modulation of the recording medium according to the present invention.

### DETAILED DESCRIPTION OF A PREFERRED EMBODIMENT

In the present invention the inventors left the conventional design-rule and performed experiments in order to find alternative materials for producing the recording layer of an optical recording medium for recording devices recording at a blue wavelength. Surprisingly, during the experiments it turned out that good signal characteristics can also be achieved, when leaving the conventional design-rule and when choosing an organic dye compound having an absorption maximum at a wavelength that is 100 nm to 250 nm higher than the recording wavelength. This requirement can be met by known organic dye compounds used as a material for the recording layers of DVD+Rs/DVD-Rs and CD-Rs.

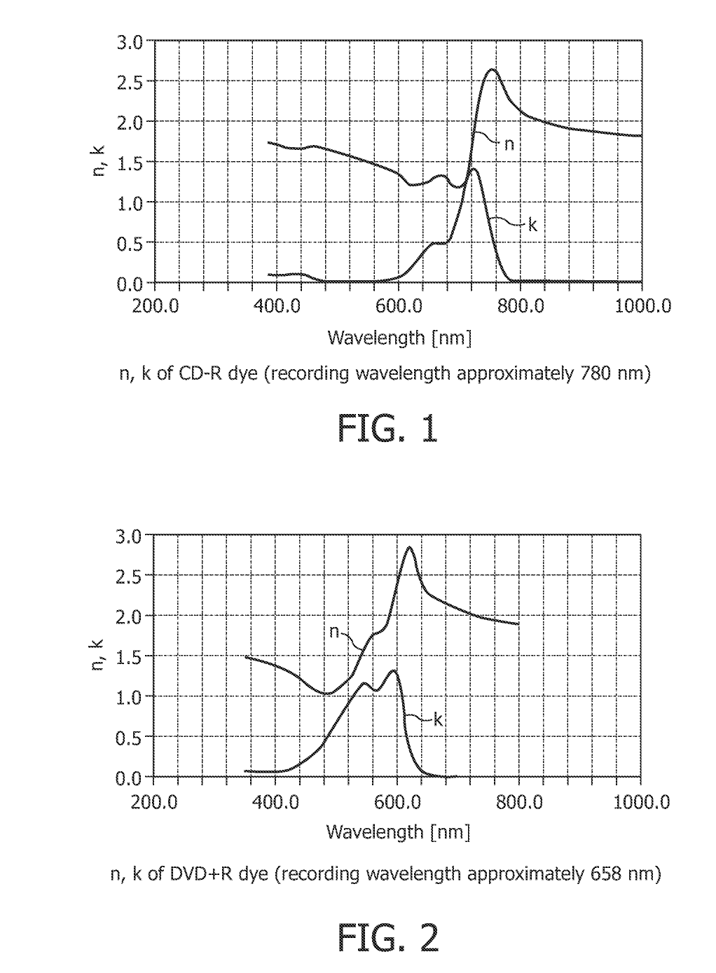

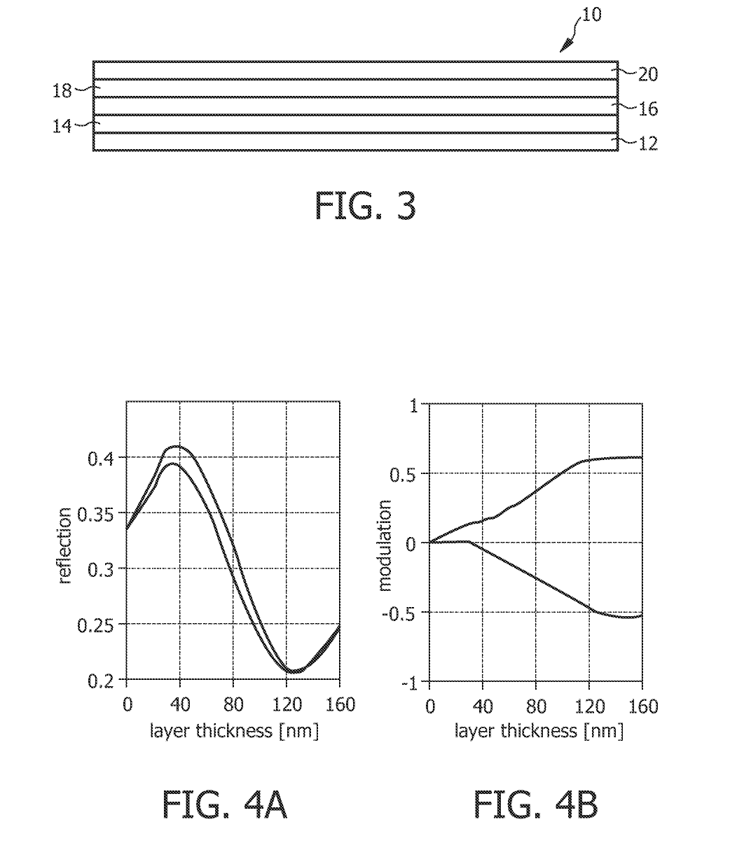

FIG. 3 illustrates a schematic cross sectional diagram of a recording medium 10 according to the present invention, and the results of a calculation are illustrated in FIG. 4A and FIG. 4B. The optical storage medium 10 the calculation is based on is designed as follows. A substrate 12 is covered with a mirror 14 made of silver (Ag), wherein the mirror 14 is preferably 150 nm thick. The mirror 14 is covered with the organic dye compound of variable thickness constituting the recording layer 16. FIG. 4A and FIG. 4B show several results for several thicknesses of the recording layer 16. The recording layer 16 is covered with a layer 18 of silicon dioxide (SiO₂) which in turn is covered with a protection layer 20. The organic dye compound used in this structure is the AZO dye for DVD+R produced by Mitsubishi Kagaku Media Co., Ltd. (MKM). This is the same dye used in connection with FIGS. 1 and 2. Even if this specific calculation was conducted on the basis of the mentioned AZO dye, also other dyes can be used, for example cyanine, phtalo-cyanine, oxonol, and all well known in the field of optical recording, as long as they fulfil the above requirement regarding their absorption maximum. In general, these are the dyes which are also suitable for forming a recording layer on a DVD-R, a DVD+R or a CD-R.

Turning now to FIG. 4A, in which calculated results for the reflection depending on the layer thickness of the recording layer 16 are shown. The upper curve shows the reflection values in case of on-groove recording conducted with low-to-high recording polarity, and the lower curve shows the reflection values in case of in-groove recording conducted with high-to-low recording polarity, wherein the latter is the preferred recording method. The laser beam used in this example has a wavelength of 350-450 nm, a so-called blu-ray laser. Similarly, in FIG. 4B, calculated results for the modulation depending on the layer thickness of the recording layer 16 are shown. In this diagram, the lower curve shows the modulation values in case of on-groove recording conducted with low-to-high recording polarity, and the upper curve shows the modulation values in case of in-groove recording conducted with high-to-low recording polarity, wherein the latter is the preferred recording method. As can be seen, satisfying reflection and modulation values are achievable at practicable recording layer thicknesses.

Thus, the present invention shows that the design rule with respect to the absorption peak is not a requirement to obtain good signal characteristics.

It should be noted that sometimes dye developers use maximum extinction of the dye in solution as an indication for the suitability as recording material, but it turns out in practice that the analysis of the position of maximum absorption in the coated dye film provides a more reliable design rule. This is related to the fact that the different molecular environment (e.g. stacking, molecular conformations, as well as dielectric screening, etc.) in the solid phase as compared to the dissolved case influences the position of the various absorption bands. Nonetheless, the general principle of the idea absorption peak location outlined here can be applied as well to screen on dye solutions albeit with lesser reliability.

In practice, the recording wavelength is inseparably connected with the optical recording medium 10, since the optical recording medium 10 has to indicate the user with what recording devices it may be used. This indication clearly defines the recording wavelength suitable for being used in connection with the recording medium 10.

1. An optical recording medium, comprising at least one recording layer being adapted to form marks upon radiation of a laser beam having a particular recording wavelength, wherein a material constituting the recording layer has an absorption maximum at a wavelength that is 100 nm to 250 nm higher than the recording wavelength.

2. The optical recording medium according to claim 1, wherein the material constituting the recording layer is an organic dye compound.

3. The optical recording medium according to claim 1, wherein the recording wavelength lies in the range of 350-450 nm.

4. The optical recording medium according to claim 2, wherein the organic dye compound is one also suitable for forming a recording layer on a DVD-R or a DVD+R.

5. The optical recording medium according to claim 2, wherein the organic dye compound is one also suitable for forming a recording layer on a CD-R.

6. Use of a material for forming a recording layer of a optical recording medium which is adapted to form marks upon radiation of a laser beam having a particular recording wavelength, wherein the material has an absorption maximum at a wavelength that is 100 nm to 250 nm higher than the recording wavelength with which the recording medium is to be recorded.
